(19) United States
(12) Patent Application Publication
(10) Pub. No.: US 2025/0221167 A1
(43) Pub. Date: Jul. 3, 2025

(54) DISPLAY APPARATUS

(71) Applicant: LG Display Co., Ltd., Seoul (KR)

(72) Inventors: Young-Hoon SON, Paju-si (KR); Mi-So KIM, Paju-si (KR)

(21) Appl. No.: 18/984,722

(22) Filed: Dec. 17, 2024

(30) Foreign Application Priority Data
Dec. 27, 2023 (KR) 10-2023-0192423

(51) Int. Cl. H10K 59/121; H10K 59/122

(52) U.S. Cl. CPC H10K 59/1213; H10K 59/122

(57) ABSTRACT

A display apparatus according to the present disclosure comprises a substrate including a plurality of pixel regions, each pixel region having a plurality of sub-pixel regions; a first light emitting device disposed in each sub-pixel region to form a plurality of sub-pixels; a first transistor configured to operate the first light emitting device; a second light emitting device disposed between sub-pixel regions of the plurality of sub-pixel regions; and a second transistor disposed between sub-pixel regions of the plurality of sub-pixel regions and configured to operate the second light emitting device. A bank layer is disposed between the plurality of sub-pixel regions and the second light emitting device is disposed over the bank layer.

### CROSS-REFERENCE TO RELATED DISCLOSURE

The disclosure claims the priority of Korea Patent Disclosure No. 10-2023-0192423, filed on Dec. 27, 2023, which is hereby incorporated by reference in its entirety.

### BACKGROUND

### Technical Field

This disclosure relates to a display apparatus having improved aperture ratio and resolution.

### Description of the Related Art

Recently, the importance of display apparatus has increased with the development of multimedia. Various display apparatus, such as liquid crystal display and organic light emitting displays, have been proposed.

The display apparatus include a plurality of sub-pixels, and the display device is disposed in each sub-pixel to display an image. In the display apparatus, structures to partition sub-pixels are required. However, these structures are areas where the images are not displayed.

### BRIEF SUMMARY

It has been found that areas where the images are not displayed lower the aperture ratio and/or resolution. Various embodiments of the present disclosure provide a display apparatus having an improved aperture ratio and high resolution.

A display apparatus according to the present disclosure comprises a substrate including a plurality of pixel regions, each pixel region having a plurality of sub-pixel regions; first light emitting device disposed in each sub-pixel region to form a plurality of sub-pixels; a first transistor configured to operate the first light emitting device; a second light emitting device disposed between adjacent sub-pixel regions of the plurality of sub-pixel regions; and a second transistor disposed between sub-pixel regions of the plurality of sub-pixel regions and configured to operate the second light emitting device; wherein a gap between the substrate and the second light emitting device is larger than a gap between the first light emitting device and the substrate. In the present disclosure, since the auxiliary sub-pixel is disposed in the area where the image is not displayed in known general display apparatus, the area where the image is displayed is increased.

A bank layer is disposed between sub-pixel regions of the plurality of sub-pixel regions and the second light emitting device is disposed over the bank layer. The bank layer may be a barrier wall which defines the sub-pixel regions therebetween.

The first light emitting device incudes a first electrode disposed in each of the plurality of sub-pixel regions, a first light emitting layer on the first electrode, and a second electrode on the first light emitting layer. The second light emitting device incudes a third electrode disposed on the bank layer, a second light emitting layer on the third electrode, and a fourth electrode on the second light emitting layer. The second electrode and the fourth electrode are integrally formed.

A first pattern and a second pattern are formed in an overhang structure between the bank layer and the second light emitting device, such that the first and second pattern are formed so as to overhang the bank layer. The first light emitting layer and the second light emitting layer are disconnected by the overhang structure.

The first transistor includes a first semiconductor layer on a buffer layer, a gate insulating layer covering the first semiconductor layer, a first gate electrode on the gate insulating layer, an interlayer insulating layer covering the first gate electrode, a first source electrode and a first drain electrode on the interlayer insulating layer. The second transistor includes a second semiconductor layer on the buffer layer, the gate insulating layer covering the second semiconductor layer, a second gate electrode on the gate insulating layer, the interlayer insulating layer covering the second gate electrode, a second source electrode and a second drain electrode on the interlayer insulating layer.

A planarization layer covers the first transistor and the second transistor and the first drain electrode is electrically connected to the first electrode through a first contact hole formed in the planarization layer. The second drain electrode is electrically connected to the third electrode through a second contact hole formed in the planarization layer, the bank layer, the first pattern, and the second pattern.

### BRIEF DESCRIPTION OF THE SEVERAL VIEWS OF THE DRAWINGS

FIG. 1 is a schematic block diagram of an organic light emitting display apparatus according to the present disclosure.

FIG. 2 is a schematic block diagram of a sub-pixel of the organic light emitting display apparatus according to the present disclosure.

FIG. 3 is a circuit diagram conceptually showing the sub-pixel of the display apparatus according to the present disclosure.

FIG. 4 is a plan view schematically showing the structure of the display apparatus according to the present disclosure.

FIG. 5 is a plan view showing the pixel structure of the display apparatus according to the present disclosure.

FIG. 6 is a plan view showing another structure of the pixel of the display apparatus according to the present disclosure.

FIG. 7 is a cross sectional view of the display apparatus according to an example of the present disclosure.

FIGS. 8A to 8H are views showing a method of manufacturing the display apparatus according to an example of the present disclosure.

### DETAILED DESCRIPTION

Advantages and features of the present disclosure and methods for achieving them will be made clear from examples described in detail below with reference to the accompanying drawings. The present disclosure may, however, be implemented in many different forms and should not be construed as being limited to the examples set forth herein, and the examples are provided such that this disclosure will be thorough and complete and will fully convey the scope of the present disclosure to those skilled in the art to which the present disclosure pertains.

Shapes, sizes, dimensions (e.g., length, width, height, thickness, radius, diameter, area, etc.), ratios, angles, numbers, and the like disclosed in the drawings for describing the examples of the present disclosure are illustrative, and thus the present disclosure is not limited to the illustrated matters.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

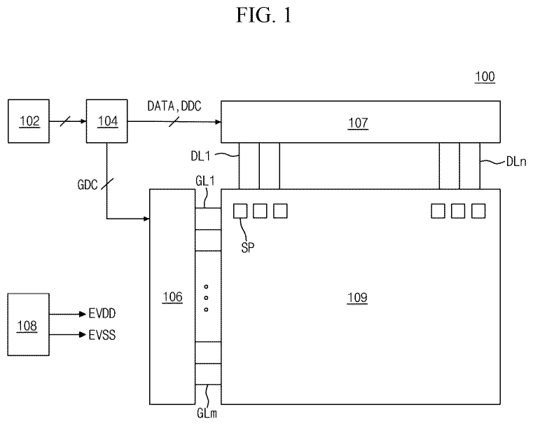

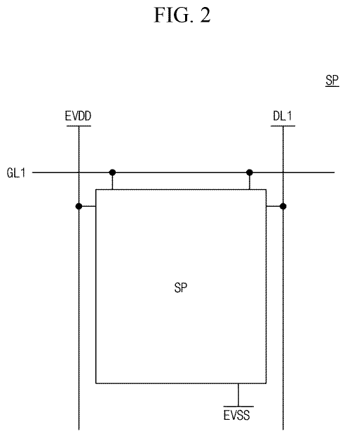

FIG. 1 is the schematic block diagram and FIG. 2 is the schematic block diagram of the sub-pixel of the organic light emitting display apparatus according to this disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside the organic light emitting display apparatus and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driver 106 includes various gate driving circuits, and the gate driving circuits may be directly formed on the substrate 110. In this case, the gate driver 106 may be a gate-in-panel (GIP).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into an analog data voltage based on a gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is not limited thereto.

In operation, the power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In operation, the voltages from the power supplying unit 108 are applied to drive the data driving unit 107 or to drive the gate driving unit 106.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include two transistors and one capacitor (it is called 2T1C), but is not limited thereto. The sub-pixel SP may be composed of 3T1C, 4T1C, 5T1C, 6T1C, 7T1C, 3T2C, 4T2C, 5T2C, 6T2C, 7T2C, 8T2C, etc. It will be understood that in the foregoing abbreviations 3T1C refers to three transistors and one capacitor; 8T2C refers to eight transistors and two capacitors; and so on.

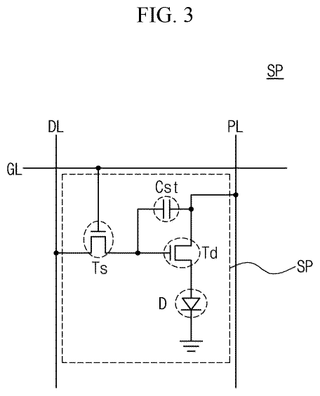

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

In operation, the driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

In operation, the storage capacitor Cst is charged with the voltage proportional to the data signal to keep the voltage of the gate electrode of the driving thin film transistor Td constant for one frame.

In FIG. 3, only two thin film transistors Td and Ts and one capacitor Cst are provided, but the present disclosure is not limited thereto. Three or more thin film transistors and two or more capacitors may be provided in the present disclosure.

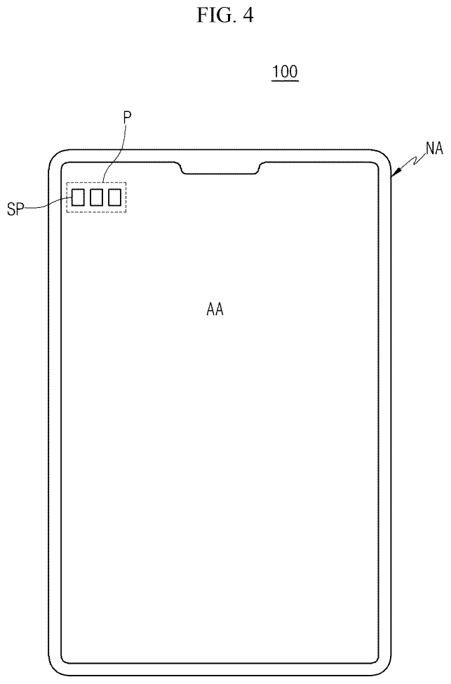

FIG. 4 is a plan view schematically showing the structure of the display apparatus 100 according to the present disclosure.

As shown in FIG. 4, the display apparatus 100 according to the present disclosure includes a display area AA for displaying an image and a non-display area NA disposed outside the display area AA.

A plurality of pixels P are arranged in the display area AA, and each pixel P includes a plurality of sub-pixels SP. The sub-pixel SP may be a red (R) sub-pixel, a green (G) sub-pixel, or a blue (B) sub-pixel. Further, the sub-pixel SP may be a white (W) sub-pixel.

Although not shown in the figure, a plurality of gate lines and data lines are arranged in the display area AA, and the sub-pixel SP is disposed in the intersection area of the gate line and data line. In each sub-pixel SP, a thin film transistor that is a switching element and a display device to display the image are disposed.

The display device may include various display devices. For example, the display device may be an organic light emitting display device, a liquid crystal display device, a quantum dot display device, a micro LED display device, or a mini LED display device.

The gate driving and the data driving unit that apply various signals to the sub-pixel SP may be disposed in the non-display area NA. The gate driving unit applies the scan signal to the sub-pixel SP through the gate line, and the data driving unit applies the image signal to the sub-pixel SP through the data line.

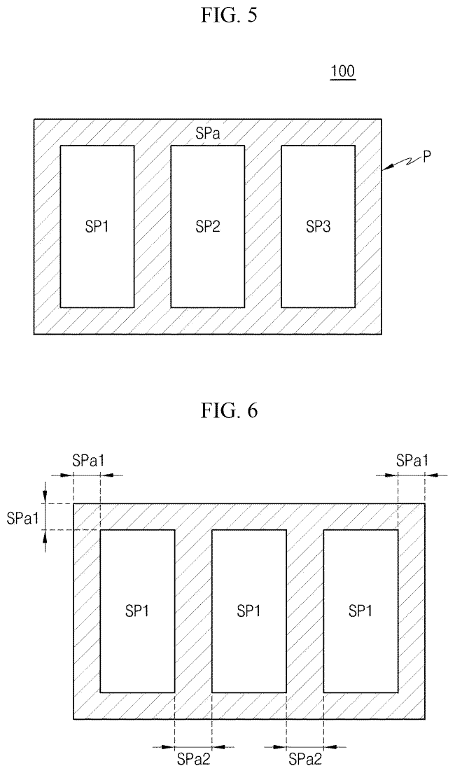

FIG. 5 is the plan view showing the structure of the pixel P of the display apparatus 100 according to the present disclosure.

As shown in FIG. 5, the pixel P of the display apparatus 100 according to the present disclosure includes first to third sub-pixels SP1, SP2, and SP3 and an auxiliary sub-pixel SPa. As shown in FIG. 5, the first to third sub-pixels SP1, SP2, and SP3 may be formed in a rectangular shape when viewed in plan view within the pixel P. In the figure, the areas of the first to third sub-pixels SP1, SP2, and SP3 when viewed in plan view are the same, but the areas of the first to third sub-pixels SP1, SP2, and SP3 may be different.

Further, the first to third sub-pixels SP1, SP2, and SP3 may be formed in various shapes when viewed in plan view. For example, the first to third sub-pixels SP1, SP2, and SP3 may be formed in a rhombus shape, pentagon shape, hexagon shape, triangle shape, circular shape, or oval shape. Additionally, the first to third sub-pixels SP1, SP2, and SP3 may be formed in different shapes.

The auxiliary sub-pixel SPa may be formed outside of the first to third sub-pixels SP1, SP2, and SP3 and/or at a periphery of the pixel P. That is, the auxiliary sub-pixel SPa may be formed in an area where the structure dividing the first to third sub-pixels SP1, SP2, and SP3 is disposed. Therefore, in the present disclosure, since the auxiliary sub-pixel SPa is disposed in the area where the image is not displayed in known general display apparatus, the area where the image is displayed can be increased so that the aperture ratio of the display apparatus 100 can be improved. Further, in the present disclosure, since the image is displayed in the non-display area where the image was not displayed in the general display apparatus, the desired image can be displayed even if the area of the pixel P is reduced so that the high resolution display apparatus 100 can be manufactured.

The first to third sub-pixels SP1, SP2, and SP3 may be the red (R) sub-pixel, the green (G) sub-pixel, and the blue (B) sub-pixel, respectively, but are not limited thereto. The auxiliary sub-pixel SPa may be any one of the red (R) sub-pixel, the green (G) sub-pixel, and the blue (B) sub-pixel.

FIG. 6 is a plan view showing another structure of the pixel P of the display apparatus 100 according to the present disclosure. In the display apparatus 100 of this structure, the auxiliary sub-pixel SPa may include a plurality of auxiliary sub-pixels SPa1 and SPa2. In the figure, the first auxiliary sub-pixel SPa1 is set as the area outside the pixel P, and the second auxiliary sub-pixel SPa2 is set as the area between the first to third sub-pixels SP1, SP2, and SP3, but is not limited thereto. For example, the auxiliary sub-pixel SPa may include three or more auxiliary sub-pixels.

The first auxiliary sub-pixel SPa1 and the second auxiliary sub-pixel SPa2 may be auxiliary sub-pixels of different colors. For example, the first auxiliary sub-pixel SPa1 and the second auxiliary sub-pixel SPa2 are sub-pixels of different colors among the red (R) sub-pixel, the green (G) sub-pixel, and the blue (B) sub-pixel.

In the present disclosure, when a first light emitting device and a second light emitting device are referred to as having a same color, this means that the peak emission wavelengths of the first and second light emitting devices are within at most 90 nm of each other. Similarly, when first and second light emitting devices are referred to as having different colors, the peak emission wavelengths of the first and second light emitting devices have wavelengths that differ by at least 90 nm.

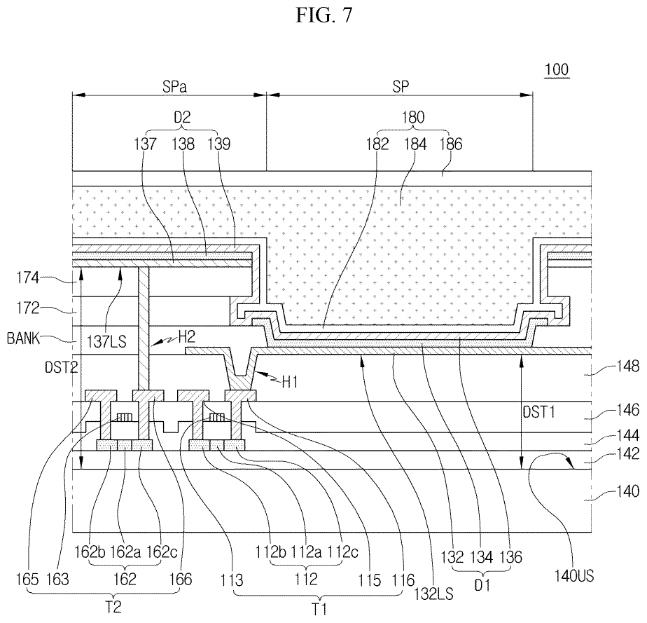

FIG. 7 is a cross-sectional view of the display apparatus 100 according to an example of the present disclosure. For convenience of explanation, only one sub-pixel region SP and auxiliary sub-pixel region SPa are shown in the figure. In FIG. 7, a sub-pixel region is the region where the sub-pixel is disposed and an auxiliary sub-pixel region is the region wherein an auxiliary sub-pixel region is disposed. The sub-pixel region and the auxiliary sub-pixel region use same reference as the sub-pixel and the auxiliary sub-pixel, respectively.

As shown in FIG. 7, the substrate 140 includes a plurality of sub-pixel regions SP and the auxiliary sub-pixel region SPa. The substrate 140 may be made of a hard material such as glass or a flexible plastic based material.

When the substrate 140 is made of the plastic based material, the substrate is made of at least one of a polyimide, a polymethylmethacrylate, a polyethylene tereththalate, a Polyethersulfone, and a Polycarbonate, but is not limited thereto.

When the substrate 140 is made of polyimide, the substrate 140 may be made of a plurality of polyimide layers, and an inorganic layer may be further disposed between the polyimide layers, but is not limited thereto.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A first thin film transistor T1 is disposed on the buffer layer 142 adjacent the sub-pixel region SP, for example in the auxiliary sub-pixel region SPa. However, in some examples (not shown in FIG. 7), the first thin film transistor T1 may be located in the sub-pixel region SP. A second thin film transistor T2 is disposed on the buffer layer in the auxiliary sub-pixel region SPa. For convenience of description, only the driving thin film transistor among various thin film transistors that may be disposed in the display area AA is illustrated, but other thin film transistors such as switching thin film transistors may also be included. In FIG. 7, the thin film transistor of a top gate structure is shown, but the thin film transistor is not limited to this structure and may be formed in other structures such as the thin film transistor of a bottom gate structure.

The first thin film transistor T1 includes a first semiconductor layer 112 disposed on the buffer layer 142, a gate insulating layer 144 covering the first semiconductor layer 112, a first gate electrode 113 on the gate insulating layer 144, an interlayer insulating layer 146 covering the first gate electrode 113, and a first source electrode 115 and a first drain electrode 116 on the interlayer insulating layer 146.

The second thin film transistor T2 includes a second semiconductor layer 162 disposed on the buffer layer 142, the gate insulating layer 144 covering the second semiconductor layer 162, a second gate electrode 163 on the gate insulating layer 144, the interlayer insulating layer 146 covering the second gate electrode 163, and a second source electrode 165 and a second drain electrode 166 on the interlayer insulating layer 146.

The first and second semiconductor layers 112 and 162 may be made of a polycrystalline semiconductor. For example, the polycrystalline semiconductor may be made of low temperature poly silicon (LTPS) having high mobility, but is not limited thereto.

The first and second semiconductor layers 112 and 162 may be made of an oxide semiconductor. For example, the first and second semiconductor layers 112 and 162 may be made of one of IGZO (Indium-gallium-zinc-oxide), IZO (Indium-zinc-oxide), IGTO (Indium-gallium-tin-oxide), and IGO (Indium-gallium-oxide), but is not limited thereto.

The first and second semiconductor layers 112 and 162 may be made of different materials. For example, the first semiconductor layer 112 may be made of the oxide semiconductor and the second semiconductor layer 162 may be made of the polycrystalline semiconductor. Further, the first semiconductor layer 112 may be made of the polycrystalline semiconductor and the second semiconductor layer 162 may be made of the oxide semiconductor.

The first semiconductor layer 112 includes a first channel region 112a in a central region and a first source region 112b and a first drain region 112c which are doped layers at the both sides of the first channel region 112a. The second semiconductor layer 162 includes a second channel region 162a in the central region and a second source region 162b and a second drain region 162c which are doped layers at the both sides of the second channel region 162a.

The gate insulating layer 144 may be composed of a single layer or multiple layers made of an inorganic material such as SiOx or SiNx, but is not limited thereto.

The first and second gate electrodes 113 and 163 are made of a metal. For example, the first and second gate electrodes 113 and 163 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The first and second source electrodes 115 and 165 and the first and second drain electrodes 115 and 165 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The first and second source electrodes 115 and 165 and the first and second drain electrodes 115 and 165 may be respectively contacted to the first and second source regions 112b and 162b and the first and second drain regions 112c and 162c of the first and second semiconductor layers 112 and 162 through contact holes formed in the gate insulating layer 144 and the interlayer insulating layer 146.

Not shown in FIG. 7, a bottom shield metal layer may be disposed on the substrate 140 under the first and second semiconductor layers 112 and 162. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the first and second thin film transistors T1 and T2 are disposed. The planarization layer 148 may be formed of the organic material such as photoacrylic. But it is not limited thereto. The planarization layer 148 may include a plurality of layers including the inorganic layer and the organic layer.

A first light emitting device D1 is disposed on the planarization layer 148. The first light emitting device D1 includes a first electrode 132, a first light emitting layer 134, and a second electrode 136.

The first electrode 132 may be an anode electrode. The first electrode 132 is disposed on the planarization layer 148 and electrically connected to the first drain electrode 116 of the first thin film transistor T1 through the first contact hole H1 formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer BANK is formed over the planarization layer 148 in the auxiliary sub-pixel region SPa. The bank layer 152 may be a barrier wall to define sub-pixels and/or sub-pixel regions. For example, opening areas formed through the bank layer 152 may at least partially define the sub-pixel regions. Auxiliary sub-pixel regions SPa may be defined as regions between adjacent or between opening areas. The bank layer BANK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

A first pattern 172 and a second pattern 174 are formed on the bank layer BANK. In the example of FIG. 7 the width of the first pattern 172 is smaller than that of the second pattern 174, thereby forming an undercut or overhang having a reverse step at the boundary between the first pattern 172 and the second pattern 174.

The first pattern 172 may be made of the inorganic insulating material such as SiOx or SiNx, and the second pattern 174 may be made of the amorphous silicon, but are not limited thereto.

The first light emitting layer 134 is formed on the upper surface of the first electrode 132 exposed to the outside through the opening area between the bank layers BANK. As will be described in detail later, the first light emitting layer 134 is formed on a plurality of sub-pixel regions SP at once through the same process, but the first light emitting layer 134 is disconnected between the adjacent sub-pixel regions SP.

In other words, the first light emitting layer 134 is deposited over the entire area of the substrate 140, but portions of the first light emitting layer 134 are disconnected from each other due to the overhang structure of the first and second patterns 172 and 174. As a result, the first light emitting layers 134 formed in the adjacent sub-pixel regions SP are disconnected.

For example, the first light emitting layer 134 may be an organic light emitting layer. Further, the first light emitting layer 134 may be an inorganic light emitting layer, such as a nano-sized material layer, quantum dot layer, micro LED light emitting layer, or mini LED light emitting layer, but is not limited thereto.

When the first light emitting layer 134 is the organic light emitting layer, the first light emitting layer 134 includes a blue organic light emitting layer and a yellow light emitting layer to output white light. The first light emitting layer 134 may be formed in a multi-stack structure. For example, when the first light emitting layer 134 is formed in a triple stack structure, the first to third stacks may be disposed with two charge generation layers therebetween. Each of the first to third stacks may include an organic light emitting layer, a hole injection layer, a hole transport layer, an electron transport layer, and an electron injection layer. For example, the organic light emitting layer of the first stack may emit red light, the organic light emitting layer of the second stack may emit blue light, and the organic light emitting layer of the third stack may emit green light.

A second light emitting layer D2 is disposed over the bank layer BANK, that is, on the second pattern 174. The second light emitting device D2 includes a third electrode 137, a second light emitting layer 138, and a fourth electrode 139. As shown in FIG. 7, a vertical gap (i.e., gap in a direction perpendicular to the plane of the substrate) between the substrate 140 and the first light-emitting device D1 is smaller than a corresponding gap between the substrate 140 and the second light-emitting device D2. In other words, the first light-emitting device D1 is disposed between the substrate 140 and the second light emitting device D2 from a cross-sectional view as shown in FIG. 7. In addition, the first light-emitting device D1 and the substrate 140 is spaced apart from each other at a first distance DST1. To be specific, the first distance DST1 is defined as the distance or the vertical gap between an upper surface 140US of the substrate 140 and a lower surface 132LS of the first electrode 132 of the first light-emitting device D1. On the other hand, the second light-emitting device D2 and the substrate 140 is spaced apart from each other at a second distance DST2. To be specific, the second distance DST2 is defined as the distance or the vertical gap between the upper surface 140US of the substrate 140 and a lower surface 137LS of the third electrode 137 of the second light-emitting device D2. The first distance DST1 is smaller than the second distance DST2, and therefore, the first light-emitting device D1 is closer to the substrate 140 than the second light-emitting device D2.

The third electrode 137 may be the anode electrode. The third electrode 137 is disposed on the second pattern 174 and electrically connected to the second drain electrode 166 of the second thin film transistor T2 through the second contact hole H21 formed in the first pattern 172, the second pattern 174, the bank layer BANK, and the planarization layer 148. The third electrode 137 may be formed of at least one of silver (Ag), aluminum (Al), gold (Au), molybdenum (Mo), tungsten (W), chromium (Cr), or an alloy thereof. Further, the third electrode 137 may be formed of a transparent metal oxide material such as indium tin oxide (ITO) or indium zinc oxide (IZO).

The third electrode 137 may be made of the same material as the first electrode of the first light emitting device D1, but may also be made of a different material from the first electrode of the first light emitting device D1.

When the display apparatus 100 is the top emission type display apparatus, the third electrode 137 may further include an opaque conductive material layer to function as a reflective electrode that reflects light. When the display apparatus 100 is a bottom emission type display apparatus, the third electrode 137 may be made of the transparent conductive material such as ITO or IZO.

The second light emitting layer 138 is formed on the upper surface of the third electrode 137. Since the second light emitting layer 138 is formed on the first pattern 172 and the second pattern 174 forms the overhang structure, the second light emitting layer 138 formed in the auxiliary sub-pixel region SPa is disconnected from the first light emitting layer 134 formed in the sub-pixel region SP.

Like the first light emitting layer 134, the second light emitting layer 138 may be composed of an organic light emitting layer, a nano-sized material layer, a quantum dots layer, a micro LED light emitting layer, or a mini LED light emitting layer. Further, the second light emitting layer 138 may be formed in a multi-stack structure.

That is, the second light emitting layer 138 may be formed of the same material and the same structure as the first light emitting layer 134, but may also be formed of the different material and the different structure from the first light-emitting layer 134.

The fourth electrode 139 may be a cathode electrode. The fourth electrode 138 is disposed on the second light emitting layer 1138. The fourth electrode 138 may be formed of the single layer or the multiple layers made of the metal or the alloy thereof. Further, the fourth electrode 139 may be made of a transparent metal oxide such as ITO or IZO, but is not limited thereto.

The fourth electrode 139 may be formed integrally with the second electrode 136. That is, the metal or the metal oxide is deposited over the entire area of the substrate 140 so that the common cathode electrodes of the sub-pixel SP and the auxiliary sub-pixel sPa can be formed integrally.

An encapsulation layer 180 is formed in the sub-pixel SP and the auxiliary sub-pixel SPa to encapsulate the first and second light emitting devices D1 and D2. When the first and second light emitting devices D1 and D2 are exposed to impurities such as moisture or oxygen, a pixel shrinkage phenomenon in which the light emitting area is reduced or the defect such as a dark spot in the light emitting area may occur. Further, moisture or oxygen penetrating into the first and second light emitting devices D1 and D2 oxidizes the metal electrode. The encapsulation layer 180 blocks impurities such as the oxygen and the moisture from the outside to prevent defects of the first and second light emitting devices D and various electrodes.

The encapsulation layer 180 may be formed of a first encapsulation layer 182, a second encapsulation layer 184, and a third encapsulation layer 186, but is not limited thereto. The encapsulation layer 180 may be formed of two layers having organic layer and inorganic layer or four or more layers having organic layers and inorganic layers.

The first encapsulation layer 182 and the third encapsulation layer 186 may be formed of the single layer or the multiple layers containing the inorganic material such as SiOx, SiON, SiNx, etc. At this time, the organic materials may be further disposed among the inorganic materials, but are not limited thereto. The second encapsulation layer 184 may be made of the organic insulating material such as acrylic resin, epoxy resin, polyimide, polyethylene, or silicon oxycarbon (SiOC), but is not limited thereto. Further, the third encapsulation layer 186 may be made of thin metal (Face Seal Metal), but is not limited thereto.

Not shown in FIG. 7, a touch member may be disposed on the encapsulation layer 180. The touch member can detect external touch information using a user's finger or a touch pen.

As described above, in the display apparatus 100 according to the present disclosure, since the auxiliary sub-pixel region SPa is formed in the region between the sub-pixel regions SP and the region outside the pixel P over the bank layer BANK and the second light emitting device D2 is disposed in the auxiliary sub-pixel region SPa, the area for displaying the image can be increased. As a result, the aperture ratio of the display apparatus 100 is improved and the high-resolution display apparatus 100 can be manufactured.

Hereinafter, the manufacturing method of the display apparatus according to an example of the present disclosure will be described in detail.

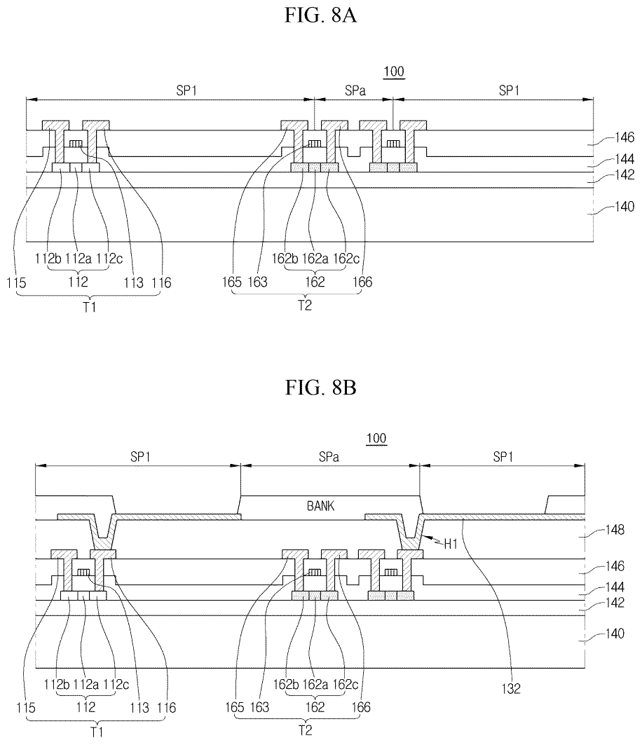

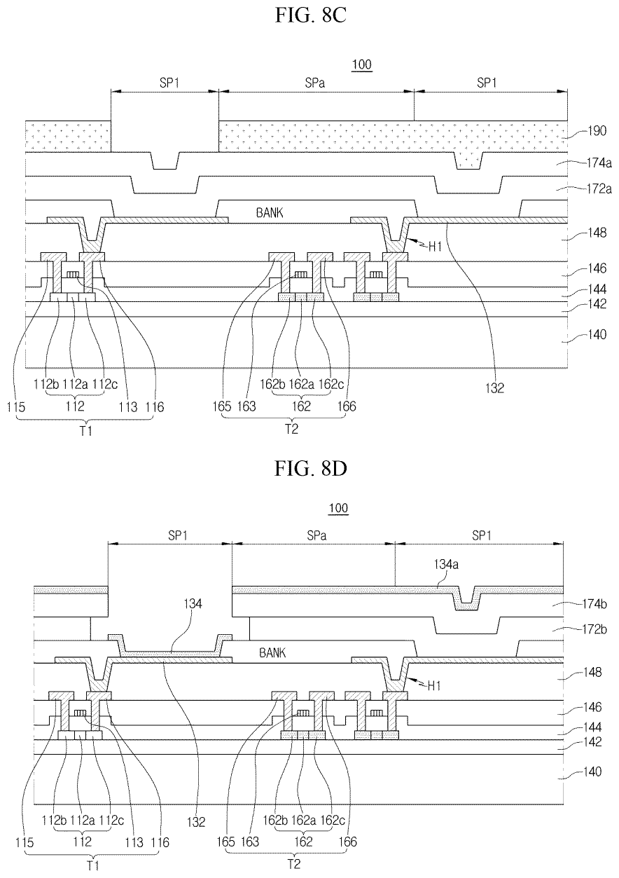

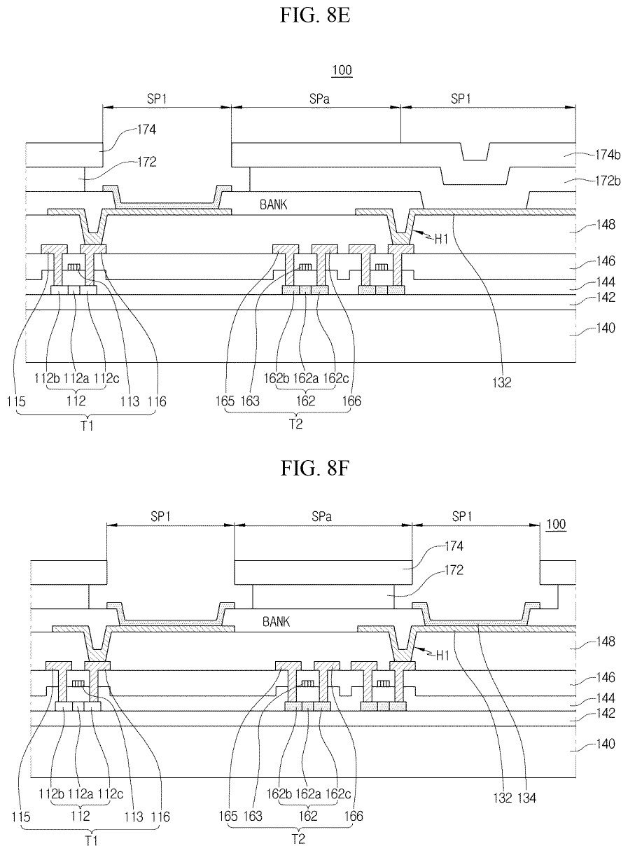

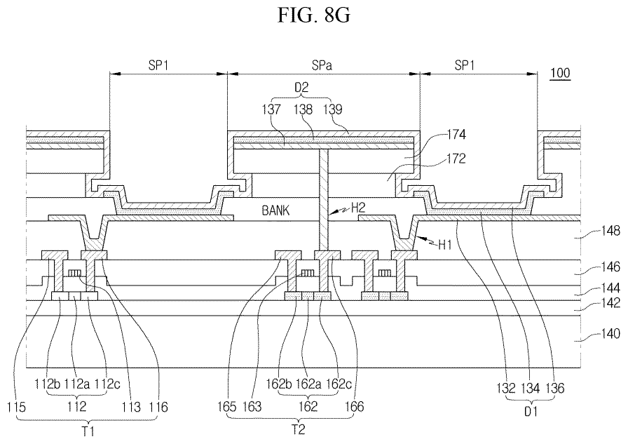

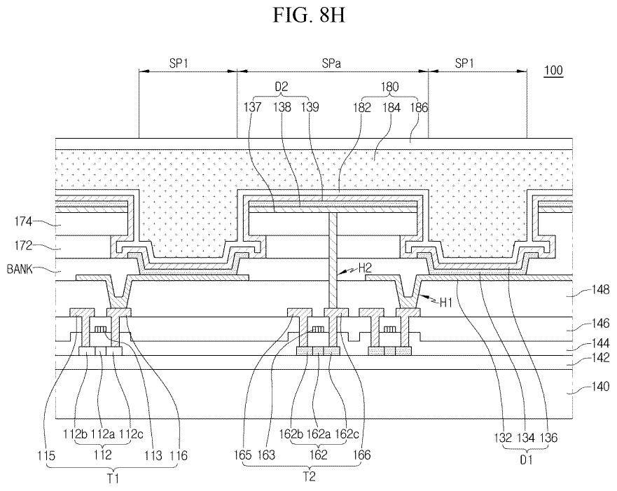

FIGS. 8A-8H are views showing the manufacturing method of the display apparatus 100 according to the present disclosure. For ease of explanation, only two sub-pixel regions SP1 and SP2 and one auxiliary sub-pixel region SPa are shown in FIGS. 8A-8H.

First, as shown in FIG. 8A, the buffer layer 142 is formed over the entire substrate 140 including a plurality of sub-pixel regions SP1 and SP2 and in the auxiliary sub-pixel region SPa. The substrate 140 may be made of the hard material such as the glass or the plastic material such as the plastic material may include a polyimide, a polymethylmethacrylate, a polyethylene tereththalate, a Polyethersulfone, and a Polycarbonate. The buffer layer 142 may be formed of the single layer of SiNx or SiOx, or multiple layers thereof.

Thereafter, the poly-crystalline semiconductor material such as poly-silicon or the oxide semiconductor material such as etching IGZO (Indium-gallium-zinc-oxide), IZO (Indium-zinc-oxide), IGTO (Indium-gallium-tin-oxide), and IGO (Indium-gallium-oxide) is deposed and etched to form the first semiconductor layer 112 in each of the sub-pixel regions SP1 and SP2 and to form the second semiconductor layer 162 in the auxiliary sub-pixel regions SPa. Further, the impurities are doped into the both sides of the first and second semiconductor layers 112 and 162 to form the first and second channel regions 112a and 162a, the first and second source regions 112b and 162b, and the first and the second drain regions 112c and 162c.

Subsequently, the gate insulating layer is formed 144 by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the first gate electrode 114 in the each sub-pixel regions SP1 and SP2 and to form the second gate electrode 163 in the auxiliary sub-pixel region SPa.

Thereafter, an organic material such as photo acrylic material or an inorganic material such as SiNx or SiOx is deposited on the first and second gate electrodes 113 and 163 to form the interlayer insulating layer 146, and then the interlayer insulating layer 146 over the first source region 112b and the first drain region 112c of the first semiconductor layer 112 and over second source region 162b and the second drain region 162c of the second semiconductor layer 162 is dry-etched to form the contact holes therein.

Subsequently, a metal such as Cr, Mo, Ta, Cu, Ti, Al, or an Al alloy is deposited by the sputtering method and etched to form the first source electrode 115 and the first drain electrode 116 which are respectively ohmic-contacted to the first source region 112b and the first drain region 112c of the first semiconductor layer 112 through the contact holes in each sub-pixel regions SP1 and SP2 and to form the second source electrode 165 and the second drain electrode 166 which are respectively ohmic-contacted to the second source region 162b and the second drain region 162c of the second semiconductor layer 162 through the contact holes in the auxiliary sub-pixel regions SPa.

Subsequently, as shown in FIG. 8B, the planarization layer 148 is formed by depositing an organic material such as photo-acryl on the first and second source electrodes 115 and 165 and the first and second drain electrodes 116 and 166, and then the planarization layer 148 on the drain electrode 115 is dry-etched to form the first contact hole H1. Thereafter, metals such as silver (Ag), aluminum (Al), gold (Au), molybdenum (Mo), tungsten (W), chromium (Cr), or the alloys thereof, or metal oxides such as ITO or IZO are deposited by the sputtering process and then etching by the wet etching process to form the first electrode 132 on the upper surface of the planarization layer 148 of the sub-pixel regions SP1 and SP2. The first electrode 132 is electrically connected to the drain electrode 116 of the first thin film transistor T1 through the first contact hole H1.

Thereafter, at least one material of the inorganic insulating material such as SiNx or SiOx, the organic material such as BCB (BenzoCycloButene), acrylic resin, epoxy resin, phenolic resin, polyamide resin, and polyimide resin, and the photoresist including the black pigment is deposited on the planarization layer 148 and the first electrode 132 and dry-etched to form the bank layer BANK.

The bank layer BANK is formed in a matrix shape over the entire area of the substrate 140 and overlapped with the edge of the first electrode 132, so that the first electrode 132 is exposed to the outside through the opening between the bank layers BANK.

Subsequently, as shown in FIG. 8C, the first insulating layer 172a and the second insulating layer 174a are continuously deposited over the entire area of the substrate 140, and then photoresist is deposited thereon and patterned to form a photoresist pattern 190. The photoresist pattern 190 is then removed from the first sub-pixel region SP1 and formed only on the second sub-pixel region SP2 and the auxiliary sub-pixel region SPa.

Subsequently, as shown in FIG. 8D, the first insulating layer 172a and second insulating layer 174a disposed below the photoresist pattern 190 are etched using the photoresist pattern 190 to form the first insulating pattern 172b and the second insulating layer. The first insulating layer 172a is made of inorganic materials such as SiOx or SiNx, and the second insulating layer 174a may be made of amorphous silicon, but is not limited thereto.

The second insulating layer 174 formed of the inorganic material such as SiOx or SiNx is etched by the dry etching process and the first insulating layer 172a formed of the amorphous silicon is etched by the wet etching process. Since the first insulating layer 172a is isotopically etched during wet etching process, a part of the first insulating layer 172a below the second insulating pattern 174b is also etched, so that the width of the first insulating pattern 172b is smaller than that of the second insulating pattern 174b thereon. Therefore, the first insulating pattern 172b and the second insulating pattern 174b adjacent to the first sub-pixel region SP1 are formed in the undercut structure or the overhang structure.

Thereafter, the light emitting material such as the organic light emitting material is deposited over the entire area of the substrate 140 to form the light emitting layer 134 on the first electrode 132 that is not blocked by the first insulating pattern 172b and the second insulating layer 174b in the first sub-pixel region, and the light emitting pattern 134a is formed on the first insulating pattern 172b and the second insulating layer 174b. The first light emitting layer 134 and the light emitting pattern 134a are disconnected from each other by the undercut structure or overhang structure of the first insulating pattern 172b and the second insulating pattern 174b.

Subsequently, as shown in FIG. 8E, the light emitting pattern 134a is removed from the first and second insulating patterns 172b and 174b.

Thereafter, the processes of FIGS. 8C-8E are repeated to form the first light emitting layer 134 on the first electrode 132 of the second sub-pixel region SP2, as shown in FIG. 8F.

If the pixel P of the display apparatus includes three sub-pixels SP of R, G, and B, the processes of FIGS. 8C to 8E are repeated three times to form the first light emitting layer 143 in each of R,G,B sub-pixels SP. If the pixel P of the display apparatus includes four sub-pixels SP, the processes of FIGS. 8C to 8E are repeated four times to form the first light emitting layer 143 in each of 4 sub-pixels SP.

Thereafter, as shown in FIG. 8G, the second contact hole H2 is formed in the planarization layer 148, the bank layer BANK, the first pattern 172, and the second pattern 174 over the second drain electrode 166 of the second thin film transistor T2 disposed in the auxiliary sub-pixel region SPa. Subsequently, the metal, the alloy thereof, or the metal oxide is deposited over the entire area of the substrate 140 and then etched to form the third electrode 137 connected electrically to the second drain electrode 166 over the second pattern 174 of the auxiliary sub-pixel region SPa.

Subsequently, the light emitting material is deposited over the entire area of the substrate 140 and then patterned to form the second light emitting layer 138 on the third electrode 137.

Thereafter, the metal or the metal oxide is deposited over the entire area of the substrate 140 to form the second electrode 136 on the first light emitting layer 134 of the sub-pixels SP1 and SP2, and to form the fourth electrode 139 on the second light emitting layer 138 of the auxiliary sub-pixel SPa.

The second electrode 136 and the fourth electrode 139 are thereby formed on the first emitting layer 134 of the sub-pixels SP1 and SP2, on the second emitting layer 138 of the auxiliary sub-pixel SPa, and on the side surfaces of the bank layer BANK, the first pattern 172, and the second pattern 174 to form the cathode electrode which is continuous common layer.

Subsequently, as shown in FIG. 8H, the inorganic material is applied over the entire area of substrate 140 to form the first encapsulation layer 382, and the organic material is applied on the first encapsulation layer 382 to form the second encapsulation layer 384. Thereafter, the inorganic material is applied on the second encapsulation layer 384 to form the third encapsulation layer 386, thereby forming the encapsulation layer 380 to seal the display apparatus 300.

As described above, in the display apparatus 100 according to the present disclosure, the first pattern 172 and the second pattern 174 of the undercut structure or the overhang structure are formed and the light emitting material is simply deposited without patterning process to form the patterned first light emitting layer 134 in each sub-pixel region, so that the manufacturing method can be simplified compared to the conventional method.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the examples disclosed in the present disclosure are not intended to limit the technical spirit of the present disclosure, but to explain, and the scope of the technical spirit of the present disclosure is not limited by these examples.

The various embodiments described above can be combined to provide further embodiments. Other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a plurality of pixel regions, each pixel region having a plurality of sub-pixel regions;
a first light emitting device disposed in each sub-pixel region to form a plurality of sub-pixels;
a first transistor configured to operate the first light emitting device;
a second light emitting device disposed between adjacent sub-pixel regions of the plurality of sub-pixel regions; and
a second transistor disposed between adjacent sub-pixel regions of the plurality of sub-pixel regions, the second transistor configured to operate the second light emitting device;
wherein a distance between the substrate and the second light emitting device is larger than a distance between the first light emitting device and the substrate.

2. The display apparatus of claim 1, further comprising a bank layer between the plurality of sub-pixel regions.

3. The display apparatus of claim 2, wherein the bank layer comprises a plurality of opening areas formed therethrough, and
wherein the plurality of sub-pixel regions corresponds to the plurality of opening areas.

4. The display apparatus of claim 3, wherein the first light emitting device is disposed in each of the opening areas.

5. The display apparatus of claim 2, wherein the second light emitting device is disposed over the bank layer.

6. The display apparatus of claim 5, wherein the first light emitting device incudes:
a first electrode disposed in each of the plurality of sub-pixel regions;
a first light emitting layer on the first electrode; and
a second electrode on the first light emitting layer.

7. The display apparatus of claim 6, wherein the second light emitting device incudes:
a third electrode on the bank layer;
a second light emitting layer on the third electrode; and
a fourth electrode on the second light emitting layer.

8. The display apparatus of claim 7, wherein the second electrode and the fourth electrode are integrally formed.

9. The display apparatus of claim 7, wherein a first pattern and a second pattern are disposed between the bank layer and the second light emitting device.

10. The display apparatus of claim 9, wherein the first pattern and the second pattern comprise an overhang structure which forms a step overhanging the bank layer.

11. The display apparatus of claim 10, wherein the first light emitting layer and the second light emitting layer are disconnected by the overhang structure.

12. The display apparatus of claim 7, wherein the first transistor includes a first semiconductor layer on a buffer layer, a gate insulating layer covering the first semiconductor layer, a first gate electrode on the gate insulating layer, an interlayer insulating layer covering the first gate electrode, a first source electrode and a first drain electrode on the interlayer insulating layer, and
wherein the second transistor includes a second semiconductor layer on the buffer layer, the gate insulating layer covering the second semiconductor layer, a second gate electrode on the gate insulating layer, the interlayer insulating layer covering the second gate electrode, a second source electrode and a second drain electrode on the interlayer insulating layer.

13. The display apparatus of claim 12, further comprising a planarization layer covering the first transistor and the second transistor, and
wherein the first drain electrode is electrically connected to the first electrode through a first contact hole formed in the planarization layer.

14. The display apparatus of claim 13, wherein the second drain electrode is electrically connected to the third electrode through a second contact hole formed in the planarization layer, the bank layer, the first pattern, and the second pattern.

15. A display apparatus, comprising,
a substrate including a plurality of pixels having a plurality of sub-pixel regions and at least one auxiliary sub-pixel region;
a first light emitting device disposed in each sub-pixel region to form a sub-pixel;
a second light emitting device disposed in the auxiliary sub-pixel region to form an auxiliary sub-pixel;
a first transistor configured to operate the first light emitting device; and
a second transistor disposed in the auxiliary sub-pixel region, the second transistor configured to operate the second light-emitting device,
wherein a distance between the substrate and the second light emitting device is larger than a distance between the first light emitting device and the substrate.

16. The display apparatus of claim 15, wherein the auxiliary sub-pixel includes:
a first auxiliary sub-pixel disposed between sub-pixel regions of the plurality of sub-pixel regions; and
a second auxiliary sub-pixel disposed at an outer periphery of the pixel.

17. The display apparatus of claim 16, further comprising a bank layer formed between the plurality of sub-pixels and around the outer periphery of the pixel.

18. The display apparatus of claim 17, wherein the bank layer comprises a plurality of opening areas formed therethrough, wherein the plurality of sub-pixel regions corresponds to the plurality of opening areas.

19. The display apparatus of claim 18, wherein the first light emitting device is disposed in each of the opening areas.

20. The display apparatus of claim 16, wherein the second light emitting devices of the first auxiliary sub-pixel and the second auxiliary sub-pixel emit the same color as one another.

21. The display apparatus of claim 16, wherein the second light emitting devices of the first auxiliary sub-pixel and the second auxiliary sub-pixel emit the different colors from one another.
